(19) United States
(12) Patent Application Publication
(10) Pub. No.: US 2024/0128711 A1
(43) Pub. Date: Apr. 18, 2024

(54) SEMICONDUCTOR LASER MODULE AND LASER MACHINING APPARATUS

(71) Applicant: Mitsubishi Electric Corporation, Chiyoda-ku, Tokyo (JP)

(72) Inventors: Yuki OKAMOTO, Tokyo (JP); Daisuke MORITA, Tokyo (JP)

(73) Assignee: Mitsubishi Electric Corporation, Chiyoda-ku, Tokyo (JP)

(21) Appl. No.: 18/264,827

(22) PCT Filed: Apr. 4, 2022
(86) PCT No.: PCT/JP2022/017057

§ 371 Date: Aug. 9, 2023

(30) Foreign Application Priority Data
Apr. 13, 2021 (JP) 2021-067921

(51) Int. Cl. H01S 5/0239; H01S 5/02251; H01S 5/02253; H01S 5/024

(52) U.S. Cl. CPC H01S 5/0239; H01S 5/02251; H01S 5/02253; H01S 5/02469

(57) ABSTRACT

A semiconductor laser module includes a laser emission unit including a laser diode element that emits a laser beam, and a first electrode and a second electrode that supply current to the laser diode element; a base member that supports and fixes the laser emission unit; a fast-axis collimator that collimates a fast-axis direction component of the laser beam emitted from the laser diode element; and a slow-axis collimator that collimates a slow-axis direction component of the laser beam emitted from the laser diode element. The base member protrudes in a direction of emission of the laser beam with respect to the laser emission unit. The fast-axis collimator is fixed to the laser emission unit in an optical path of the laser emission unit where the laser beam is emitted. The slow-axis collimator is fixed to the base member in the optical path of the laser beam.

### FIELD

The present disclosure relates to a semiconductor laser module that outputs a laser beam, and to a laser machining apparatus.

### BACKGROUND

A high power laser device, a typical example of which is a light source for a laser machining apparatus, includes multiple semiconductor laser modules that each emit a laser beam, and a diffraction grating that couples the laser beams emitted from the multiple semiconductor laser modules to have the optical axes thereof aligned to one another. Each of the semiconductor laser modules includes a laser diode element, and a fast-axis collimator (FAC) and a slow-axis collimator (SAC) that each shape the laser beam, disposed in an optical path of the laser beam emitted from the laser diode element.

Patent Literature 1 discloses a laser device having such configuration, capable of monitoring the states of multiple laser diode elements using a simple configuration. The laser device described in Patent Literature 1 includes a first housing that houses multiple laser diode elements and multiple FACs, and a second housing that houses multiple SACs provided for the respective laser diode elements, and a diffraction grating, where the first housing and the second housing are disposed in contact with each other. The laser device described in Patent Literature 1 also has a communication opening provided for each of the multiple laser diode elements for communication between the first housing and the second housing. An optical member coated with a coating to provide a predetermined transmittance is provided in the communication opening, and a photodiode is disposed in the optical path of a laser beam reflected by the optical member. In addition, monitoring of the reflected light of the laser beam detected by the photodiode allows the state of that laser diode element to be checked during use of the laser device.

### CITATION LIST

### Patent Literature

Patent Literature 1: Japanese Patent Application Laid-open No. 2019-192756

### SUMMARY OF INVENTION

### Problem to be Solved by the Invention

A typical laser device needs alignment to adjust the angle about Y-axis of the laser diode element, and to adjust the position in a Y-axis direction, the position in a Z-axis direction, and the angle about Z-axis, of the FAC and of the SAC when the laser beam travels along Z-axis, and the height direction of the laser device perpendicular to Z-axis is the Y-axis direction. In addition, due to the plurality of the semiconductor laser modules, the laser device described in Patent Literature 1 needs, for the entire laser device, the alignment as many times as the number of semiconductor laser modules. The technology described in Patent Literature 1 thus suffers from a problem in a high amount of work of alignment required in a single semiconductor laser module, which makes the alignment work laborious.

The present disclosure has been made in view of the foregoing, and it is an object of the present disclosure to provide a semiconductor laser module that enables a reduction in the amount of work required for alignment as compared to the conventional technology.

### Means to Solve the Problem

To solve the problem and achieve the object described above, a semiconductor laser module according to the present disclosure includes a laser emission unit, a base member, a fast-axis collimator, and a slow-axis collimator. The laser emission unit includes a laser diode element that emits a laser beam, and a first electrode and a second electrode that supply current to the laser diode element. The base member supports and fixes the laser emission unit. The fast-axis collimator collimates a fast-axis direction component of the laser beam emitted from the laser diode element. The slow-axis collimator collimates a slow-axis direction component of the laser beam emitted from the laser diode element. The base member protrudes in a direction of emission of the laser beam with respect to the laser emission unit. The fast-axis collimator is fixed to the laser emission unit in an optical path of the laser emission unit where the laser beam is emitted. The slow-axis collimator is fixed to the base member in the optical path of the laser beam.

### Effects of the Invention

The present disclosure is advantageous in that the amount of work required for alignment can be reduced as compared to the conventional technology.

### BRIEF DESCRIPTION OF DRAWINGS

FIG. 1 is a perspective view schematically illustrating an example of configuration of a semiconductor laser module according to a first embodiment.

FIG. 2 is a partial cross-sectional view schematically illustrating an example of configuration of the semiconductor laser module according to the first embodiment.

FIG. 3 is a front view schematically illustrating an example of configuration of the semiconductor laser module according to the first embodiment.

FIG. 4 is a diagram schematically illustrating an example of configuration of a laser machining apparatus according to the first embodiment.

FIG. 5 is a diagram schematically illustrating an example of configuration of a laser oscillator for use in the laser machining apparatus according to the first embodiment.

### DESCRIPTION OF EMBODIMENT

A semiconductor laser module and a laser machining apparatus according to embodiments of the present disclosure will be described in detail below with reference to the drawings.

### First Embodiment

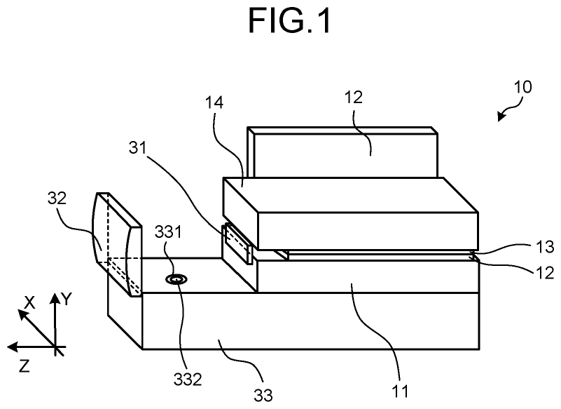

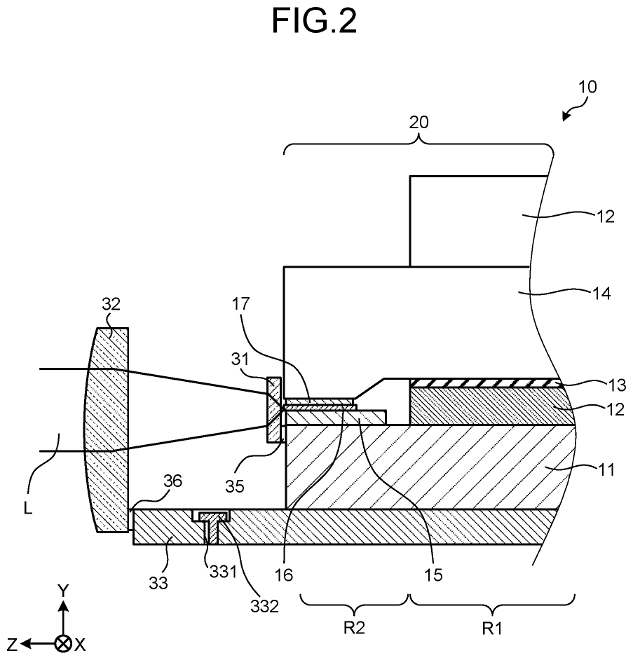

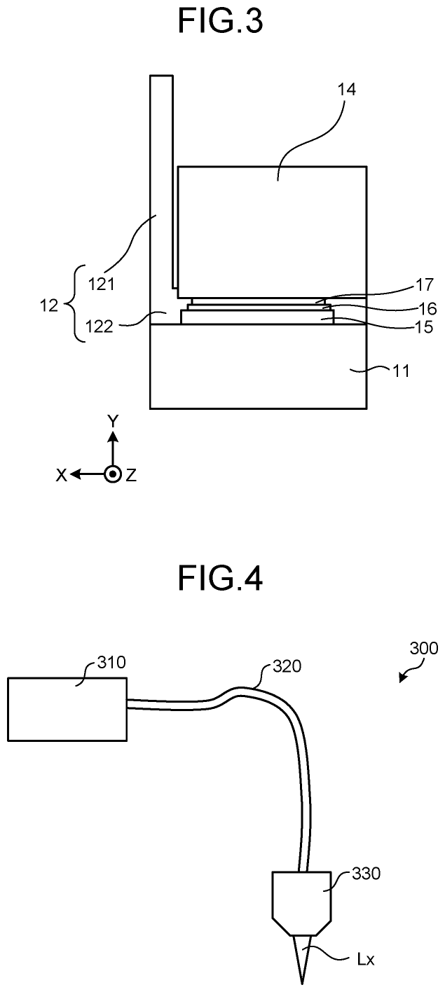

FIG. 1 is a perspective view schematically illustrating an example of configuration of a semiconductor laser module according to a first embodiment. FIG. 2 is a partial cross-sectional view schematically illustrating an example of configuration of the semiconductor laser module according to the first embodiment. FIG. 3 is a front view schematically illustrating an example of configuration of the semiconductor laser module according to the first embodiment. The following description assumes that a direction in which a laser beam L is emitted is defined as a Z-axis direction; a direction which is perpendicular to Z-axis and in which members forming a semiconductor laser module 10 are stacked one on top of another is defined as a Y-axis direction; and a direction perpendicular to both Z-axis and Y-axis is defined as an X-axis direction. A relative relationship between two positions along the Y-axis direction is hereinafter expressed in terms of upward and downward directions. In addition, it is assumed that the face on the side on which a laser diode element 16 is disposed, perpendicular to the Z-axis direction, is the front face. The cross section of FIG. 2 corresponds to a YZ-cross section of FIG. 1. Moreover, FIG. 3 illustrates a front view without SAC 32.

The semiconductor laser module 10 includes a heat sink 11, an anode electrode 12, an electrically insulating sheet 13, a cathode electrode 14, a submount 15, a laser diode element 16, and a feed structure 17.

The heat sink 11 is a heat dissipating member for reducing an increase in temperature of the laser diode element 16. The heat sink 11 has a flat plate-shaped structure extending in the Z-axis direction. The heat sink 11 is formed of a highly thermally conductive material. The heat sink 11 is herein also formed of an electrically conductive material. In one example, the heat sink 11 is formed of copper (Cu). Further in one example, the heat sink 11 includes therein a water channel for allowing cooling water to flow therethrough. The heat sink 11 has a top surface having an electrode disposition region R1 corresponding to a first region, and an element disposition region R2 corresponding to a second region.

The anode electrode 12, having an L shape in an XY-plane, is disposed in the electrode disposition region R1 of the heat sink 11. The anode electrode 12 is formed using an L-shaped member having a first portion 121 having a plate shape parallel to a YZ-plane, and a second portion 122 having a plate shape parallel to a ZX-plane. The anode electrode 12 is an electrode connected to a power supply (not illustrated) to supply current to the laser diode element 16. The anode electrode 12 is connected to a portion on the P-type semiconductor side of the laser diode element 16. The anode electrode 12 and the heat sink 11 are electrically connected to each other. The anode electrode 12 is formed of copper in one example. The anode electrode 12 corresponds to a first electrode.

The cathode electrode 14 is disposed on the second portion 122 of the anode electrode 12 with the electrically insulating sheet 13 interposed therebetween. The cathode electrode 14 has a shape and a size almost similar to the shape and the size of the heat sink 11 in a ZX-plane. That is, the cathode electrode 14 has a structure protruding with respect to the anode electrode 12 in the Z-axis direction in a ZX-plane. The cathode electrode 14 is disposed spaced apart from, and out of contact with, the first portion 121 of the anode electrode 12 in the X-direction. The cathode electrode 14 is an electrode connected to a power supply (not illustrated) to supply current to the laser diode element 16. The cathode electrode 14 is connected to a portion on the N-type semiconductor side of the laser diode element 16. The cathode electrode 14 also functions to dissipate heat generated in the laser diode element 16. The cathode electrode 14 is formed of copper in one example. The cathode electrode 14 corresponds to a second electrode.

The electrically insulating sheet 13 is an electrically insulating layer disposed on the second portion 122 of the anode electrode 12, and provided for insulation between the anode electrode 12 and the cathode electrode 14.

The laser diode element 16 is disposed in the element disposition region R2 of the heat sink 11 with the submount 15 interposed therebetween. The submount 15 is fixed on the element disposition region R2 of the heat sink 11. The submount 15 is an intermediate member for relieving stress generated in the laser diode element 16 due to a difference of linear expansion coefficient between the heat sink 11 and the laser diode element 16. That is, the submount 15 desirably has a linear expansion coefficient between the linear expansion coefficient of the laser diode element 16 and the linear expansion coefficient of the heat sink 11. The submount 15 is desirably also thermally conductive to conduct heat from the laser diode element 16 to the heat sink 11, and also electrically conductive to provide electrical connection with the anode electrode 12 via the heat sink 11. The submount 15 is formed of copper-tungsten (CuW) or aluminum nitride (AlN) in one example.

The laser diode element 16 is disposed and fixed on the submount 15. The laser diode element 16 is an edge emitting laser including a PN junction parallel to a ZX-plane to emit the laser beam L in the Z-axis direction. In the laser diode element 16, gallium arsenide (GaAs) is used for the substrate, and indium gallium arsenide (InGaAs) is used for the active layer in one example. The laser diode element 16 is disposed such that the edge face in the Z-axis direction thereof is almost aligned with the position, in the Z-axis direction, of the edge faces of the heat sink 11 and of the cathode electrode 14.

The feed structure 17 is disposed on the laser diode element 16. The feed structure 17 electrically connects the laser diode element 16 and the cathode electrode 14 to each other, and has a contact arrangement having a sufficiently large area of contact with the laser diode element 16 to function to improve the amount of heat dissipation from the top surface of the laser diode element 16.

An upper portion of the element disposition region R2 of the heat sink 11 is covered by the cathode electrode 14. The submount 15, the laser diode element 16, and the feed structure 17 are disposed in a space formed between the heat sink 11 and the cathode electrode 14.

The anode electrode 12 is electrically connected to the laser diode element 16 via the heat sink 11 and via the submount 15. The cathode electrode 14 is electrically connected to the laser diode element 16 via the feed structure 17.

Note that the foregoing description assumes that the heat sink 11 is electrically conductive, but the heat sink 11 may partially include an electrically insulating layer. This can be achieved by either use of an electrically conductive material in an upper portion of the heat sink 11, or disposition of an electrically conductive material between the heat sink 11 and the anode electrode 12 and between the heat sink 11 and the submount 15.

A structure unit for emitting the laser beam L including the heat sink 11, the anode electrode 12, the electrically insulating sheet 13, the cathode electrode 14, the submount 15, the laser diode element 16, and the feed structure 17 is hereinafter referred to as laser emission unit 20.

The semiconductor laser module 10 also includes a FAC 31, the SAC 32, and a manifold 33.

The FAC 31 is an optical component disposed on the edge face in the Z-axis direction, of the laser diode element 16 of the laser emission unit 20 to collimate a fast-axis direction component of the laser beam L emitted from the laser diode element 16. In one example, the FAC 31 is fixed on the edge face in the Z-axis direction, of the heat sink 11 using adhesive 35. The FAC 31 is adjusted in terms of the position in the Y-axis direction, the position in the Z-axis direction, and the rotation angle about Z-axis based on the shape, the diameter, and the like of the laser beam L emitted from the laser diode element 16. The FAC 31 is then fixed on the edge face of the heat sink 11 using adhesive 35 at the position in the Y-axis direction, the position in the Z-axis direction, and the rotation angle about Z-axis as adjusted. The FAC 31 is thus attached by adhesion to the heat sink 11 after alignment, meaning that alignment with the laser emission unit 20 has already been completed.

The SAC 32 is an optical component to collimate a slow-axis direction component of the laser beam L that has passed through the FAC 31.

The manifold 33 serves as a base member of the semiconductor laser module 10, and is fixed to the housing of the laser machining apparatus. The manifold 33 supports and fixes the heat sink 11, more specifically, the laser emission unit 20, on the top surface of the manifold 33. The manifold 33 also serves a relay member including a water channel to lead cooling water to the heat sink 11. The manifold 33 includes therein the water channel to lead cooling water to the heat sink 11. The water channel is connected to the water channel provided in the heat sink 11 using a connecting member. The manifold 33 is formed of steel use stainless (SUS) 303 in one example.

In the Z-axis direction, the manifold 33 protrudes in the direction of emission of the laser beam L with respect to the laser emission unit 20 on the manifold 33. That is, an edge portion in the Z-axis direction, of the manifold 33, is positioned apart from the edge portion in the Z-axis direction, of the laser emission unit 20 on the manifold 33 in the direction of emission of the laser beam L. The SAC 32 is fixed to this edge portion using adhesive 36.

The laser emission unit 20 is fixed on the manifold 33. The edge portion in the Z-axis direction, of the manifold 33, protrudes in the direction of emission of the laser beam L with respect to the edge portion in the Z-axis direction, of the laser emission unit 20 on the manifold 33.

In the first embodiment, the SAC 32 is fixed to the edge face in the Z-axis direction, of the manifold 33 using the adhesive 36 to be positioned in the optical path of the laser beam L emitted from the laser diode element 16 and passed through the FAC 31. The SAC 32 is adjusted in terms of the position in the Y-axis direction, the position in the Z-axis direction, and the rotation angle about Z-axis based on the shape, the diameter, and the like of the laser beam L emitted from the laser diode element 16. The SAC 32 is then fixed on the edge face of the manifold 33 using the adhesive 36 at the position in the Y-axis direction, the position in the Z-axis direction, and the rotation angle about Z-axis as adjusted. In this process, the surface for adhesion is the surface perpendicular to the Z-axis direction having a large position adjustment likelihood of the SAC 32. This reduces or prevents degradation in beam quality caused by misalignment in the thickness direction that may occur during curing of the adhesive 36. The SAC 32 is thus attached by adhesion to the manifold 33 after alignment, meaning that alignment in the semiconductor laser module 10 has already been completed.

In a region between the FAC 31 and the SAC 32, the manifold 33 has a through hole 331 penetrating the manifold 33, and includes a bolt 332, which is a fastening member inserted into the through hole 331. In addition, a housing of a laser machining apparatus (not illustrated) has a threaded hole for screwing the bolt 332 at the position for mounting the semiconductor laser module 10. The diameter of the through hole 331 is designed to be greater than the diameter of the threaded hole and less than the diameter of the head of the bolt 332. The bolt 332 is inserted into the through hole 331 with the position of the threaded hole made in the laser machining apparatus in alignment with the position of the through hole 331 made in the manifold 33. Then, the angle about Y-axis, of the manifold 33 is adjusted, and the bolt 332 is screwed into the threaded hole. Thus, the manifold 33 is fixed at a predetermined position of the housing of the laser machining apparatus. Note that use of the through hole 331 having a diameter greater than the diameter of the threaded hole enables the manifold 33 to be moved in a ZX-plane within the range of the diameter of the through hole 331 after the bolt 332 is unscrewed by a small amount.

In the first embodiment, alignment of the semiconductor laser module 10 can be done merely by adjustment of the angle about Y-axis of the semiconductor laser module 10 while measuring the output power of the laser beam L. This is because the FAC 31 is attached by adhesion to the laser emission unit 20 after adjustment has been made on the position in the Y-axis direction, on the position in the Z-axis direction, and on the rotation angle about Z-axis, and the SAC 32 is attached by adhesion to the manifold 33, on which the laser emission unit 20 is fixed, after adjustment has been made on the position in the Y-axis direction, on the position in the Z-axis direction, and on the rotation angle about Z-axis. Alignment in the semiconductor laser module 10 has thus already been completed. This makes the amount of work required for alignment of the semiconductor laser module 10 of the first embodiment reduced to one seventh of the amount of work required for alignment of a conventional semiconductor laser module.

Such semiconductor laser module 10 can be used as a light source of the laser beam of a laser machining apparatus. FIG. 4 is a diagram schematically illustrating an example of configuration of a laser machining apparatus according to the first embodiment. A laser machining apparatus 300 includes a laser oscillator 310, an optical fiber 320, and a machining head 330.

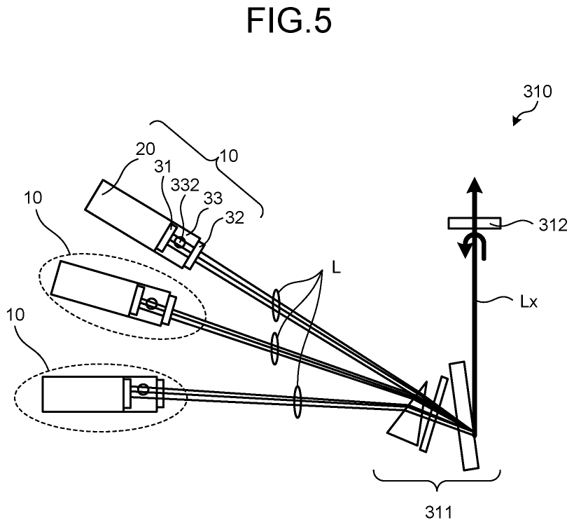

The laser oscillator 310 emits a laser beam. FIG. 5 is a diagram schematically illustrating an example of configuration of a laser oscillator for use in the laser machining apparatus according to the first embodiment. The laser oscillator 310 includes multiple semiconductor laser modules 10, an optical coupler unit 311, and an external resonant mirror 312. The semiconductor laser module 10 is configured such that, as described above, the FAC 31 is attached by adhesion to the laser emission unit 20, the laser emission unit 20 is fixed on the manifold 33, and the SAC 32 is fixed to the manifold 33. The optical coupler unit 311 couples together the laser beams L from the multiple semiconductor laser modules 10. Examples of the optical coupler unit 311 include a prism and a diffraction grating. The external resonant mirror 312 transmits part of a laser beam Lx generated by coupling in the optical coupler unit 311, and reflects the remaining part toward the semiconductor laser modules 10. The external resonant mirror 312 forms an optical resonator with the surfaces for emission of the laser beams L in the laser diode elements 16 of the semiconductor laser modules 10.

Returning to the description with reference to FIG. 4, the optical fiber 320 transmits the laser beam Lx generated by coupling in the laser oscillator 310 and emitted from the laser oscillator 310 to the machining head 330.

The machining head 330 collects the laser beam Lx propagated through the optical fiber 320, and emits the laser beam Lx to a workpiece. The machining head 330 includes a light collecting optical system that collects the laser beam Lx propagated through the optical fiber 320, and emits the laser beam Lx to a workpiece. During machining, the machining head 330 is positioned to face the position where machining is to be performed, of the workpiece.

As illustrated in FIG. 5, the laser oscillator 310 includes the multiple semiconductor laser modules 10. Each of the semiconductor laser modules 10 includes the FAC 31 and the SAC 32 integrated with the laser emission unit including the laser diode element 16, as described above. Alignment of each of the semiconductor laser modules 10 is performed by unscrewing the bolt 332 by a small amount and rotating the manifold 33 about the position of the bolt 332. Then, this alignment work is performed as many times as the number of the semiconductor laser modules 10 included in the laser oscillator 310. In the semiconductor laser module 10 of the first embodiment, the FAC 31 is attached by adhesion to the laser emission unit 20 after adjustment has been made on the position in the Y-axis direction, on the position in the Z-axis direction, and on the rotation angle about Z-axis, and the SAC 32 is attached by adhesion to the manifold 33, on which the laser emission unit 20 is fixed, after adjustment has been made on the position in the Y-axis direction, on the position in the Z-axis direction, and on the rotation angle about Z-axis. This enables alignment to be performed in the first embodiment by merely performing adjustment of the semiconductor laser module 10 about Y-axis in contrast to conventional alignment in which adjustment is individually performed on the laser emission unit 20, on the FAC 31, and on the SAC 32. That is, the amount of work required for alignment can be significantly reduced as compared to the conventional technology.

In addition, the surface for adhesion is the surface perpendicular to the Z-axis direction having a large position adjustment likelihood of the SAC 32. This can reduce or prevent degradation in beam quality caused by misalignment in the thickness direction that may occur during curing of the adhesive 36.

The configurations described in the foregoing embodiment are merely examples. These configurations may be combined with a known other technology, and moreover, part of such configurations may be omitted and/or modified without departing from the spirit thereof.

### REFERENCE SIGNS LIST

10 semiconductor laser module; 11 heat sink; 12 anode electrode; 13 electrically insulating sheet; 14 cathode electrode; 15 submount; 16 laser diode element; 17 feed structure; 20 laser emission unit; 31 FAC; 32 SAC; 33 manifold; 35, 36 adhesive; 121 first portion; 122 second portion; 300 laser machining apparatus; 310 laser oscillator; 311 optical coupler unit; 312 external resonant mirror; 320 optical fiber; 330 machining head; 331 through hole; 332 bolt; L, Lx laser beam; R1 electrode disposition region; R2 element disposition region.

1. A semiconductor laser module comprising:
a laser emission unit including a laser diode element to emit a laser beam, and a first electrode and a second electrode to supply current to the laser diode element;
a base member to support and fix the laser emission unit;
a fast-axis collimator to collimate a fast-axis direction component of the laser beam emitted from the laser diode element; and
a slow-axis collimator to collimate a slow-axis direction component of the laser beam emitted from the laser diode element, wherein
the base member protrudes in a direction of emission of the laser beam with respect to the laser emission unit,
the fast-axis collimator is fixed to the laser emission unit in an optical path of the laser emission unit where the laser beam is emitted, and
the slow-axis collimator is fixed to an edge face of the base member in a direction along the optical path, in the optical path of the laser beam.

2. The semiconductor laser module according to claim 1, wherein
the laser emission unit includes
a heat sink,
the first electrode disposed in a first region of the heat sink,
an electrically insulating layer disposed on the first electrode,
a submount being electrically conductive and thermally conductive, disposed in a second region of the heat sink, the second region being different from the first region,
the laser diode element disposed on the submount,
a feed structure being electrically conductive and thermally conductive, disposed on the laser diode element, and
the second electrode disposed on and in contact with the electrically insulating layer and the feed structure.

3. The semiconductor laser module according to claim 2, wherein
the base member is a manifold, and
the manifold and the heat sink include therein a water channel for circulating cooling water.

4. A laser machining apparatus comprising:
a laser oscillator including a plurality of the semiconductor laser modules according to claim 1, to couple the laser beams emitted from the plurality of semiconductor laser modules and to emit a laser beam generated by coupling;
an optical fiber to transmit the laser beam generated by coupling and emitted from the laser oscillator; and
a machining head to collect the laser beam generated by coupling and transmitted through the optical fiber, and to emit a laser beam collected, to a workpiece.

5. A laser machining apparatus comprising:
a laser oscillator including a plurality of the semiconductor laser modules according to claim 2, to couple the laser beams emitted from the plurality of semiconductor laser modules and to emit a laser beam generated by coupling;
an optical fiber to transmit the laser beam generated by coupling and emitted from the laser oscillator; and
a machining head to collect the laser beam generated by coupling and transmitted through the optical fiber, and to emit a laser beam collected, to a workpiece.

6. A laser machining apparatus comprising:
a laser oscillator including a plurality of the semiconductor laser modules according to claim 3, to couple the laser beams emitted from the plurality of semiconductor laser modules and to emit a laser beam generated by coupling;
an optical fiber to transmit the laser beam generated by coupling and emitted from the laser oscillator; and
a machining head to collect the laser beam generated by coupling and transmitted through the optical fiber, and to emit a laser beam collected, to a workpiece.
